(19) United States
(12) Patent Application Publication
(10) Pub. No.: US 2026/0233346 A1
(43) Pub. Date: Aug. 13, 2026

(54) SOLDER BALL

(71) Applicants: NIPPON STEEL CHEMICAL & MATERIAL CO., LTD., Tokyo (JP); NIPPON MICROMETAL CORPORATION, Saitama (JP)

(72) Inventors: Takayuki KOBAYASHI, Tokyo (JP); Tsunekazu YAMAZAKI, Saitama (JP); Kiyotsugu KOMORI, Saitama (JP); Katsuhiko HOSHINO, Saitama (JP)

(21) Appl. No.: 19/469,441

(22) PCT Filed: Mar. 21, 2024
(86) PCT No.: PCT/JP2024/011090

§ 371 Date: Sep. 26, 2025

(30) Foreign Application Priority Data
Mar. 31, 2023 (JP) 2023-058392

(51) Int. Cl. B23K 35/30; B23K 35/02; C22C 5/02

(52) U.S. Cl. CPC B23K 35/3013; B23K 35/0222; C22C 5/02

(57) ABSTRACT

A solder ball according to the present invention contains: Sn of 19 mass % or more and 25 mass % or less; a balance containing Au as a main component; and any one additional element of Mg, Al, Si, Ti, V, Cr, Mn, and Ce, in which a concentration of the additional element with respect to the entire solder ball is 0.01 ppm by weight or more and less than 0.1 ppm by weight.

### TECHNICAL FIELD

The present invention relates to a solder ball.

### BACKGROUND ART

From a viewpoint of high strength, high electrical conductivity, and the like, a solder paste and a sheet-shaped material formed of an Au—Sn-based alloy are used as a joint material for a sealing package that hermetically seals electronic devices such as a semiconductor light emitting device formed by mounting a semiconductor light-emitting element on a circuit board, a surface acoustic wave (SAW) filter, a film bulk acoustic resonator (FBAR) filter, and a crystal resonator.

PTL 1 discloses an Au—Sn-containing alloy paste in which Au—Sn alloy powder having a composition containing 20 wt % to 25 wt % Sn and a balance of Au and having a particle size of 10 μm or less, and 15 wt % to 30 wt % flux containing at least an activator are mixed.

PTL 2 discloses a method of providing a solder bump used in a flip-chip bonding technology using solder containing 80% Au and 20% Sn.

PTL 3 discloses a solder ball containing: Sn of 19 mass % or more and 25 mass % or less; a balance containing Au as a main component; and any one element of Fe, Cr, and Ni, in which a concentration of Fe in a case of containing Fe is 0.1 ppm by mass or more and 10 ppm by mass or less, a concentration of Cr in a case of containing Cr is 0.1 ppm by mass or more and 100 ppm by mass or less, and a concentration of Ni in a case of containing Ni is 1 ppm by mass or more and 5000 ppm by mass or less, with respect to the entire solder ball.

When the solder ball made of the Au—Sn-based alloy is mounted as the joint material for the sealing package or other semiconductor devices described above, a large number of solder balls are processed using a ball mounter or a solder jet device (manufactured by PacTech). When solder balls are mounted using a ball mounter, it is necessary to place the solder balls one by one in an appropriate position to prevent a mounting failure. In addition, when solder balls are mounted using a solder jet device, it is necessary to perform a process without causing clogging.

### CITATION LIST

### Patent Literature

PTL 1: JP 2014-54653 A
PTL 2: JP H05-136152 A
PTL 3: WO 2020/217833 A1

### SUMMARY OF THE INVENTION

### Technical Problem

However, if sphericity of a solder ball is not high enough, a mounting failure in a case of using a ball mounter is likely to occur, or clogging in a case of using a solder jet device is likely to occur, and productivity is reduced. This effect is particularly noticeable when a spherical diameter of the solder ball is 250 μm or less.

An object of the present invention is to provide a solder ball in which sphericity can be improved.

### Solution to Problem

A solder ball according to the present invention contains: Sn of 19 mass % or more and 25 mass % or less; a balance containing Au as a main component; and any one additional element of Mg, Al, Si, Ti, V, Cr, Mn, and Ce, in which a concentration of the additional element with respect to the entire solder ball is 0.01 ppm by weight or more and less than 0.1 ppm by weight.

### Advantageous Effects of Invention

According to the present invention, a uniform eutectic alloy made of Au and Sn is obtained, and sphericity of a solder ball can be improved.

### BRIEF DESCRIPTION OF DRAWINGS

FIG. 1 is a cross-sectional view showing a schematic diagram of a USD manufacturing apparatus used when manufacturing a solder ball by a uniform droplet spray method.

FIG. 2A is a plan view showing an example in which solder balls according to an embodiment are disposed in a close-packed manner.

FIG. 2B is a plan view showing an example in which the solder balls according to the embodiment are disposed at an interval L.

FIG. 3A is a schematic end view showing a state of the solder balls according to the embodiment before melting.

FIG. 3B is a schematic end view showing a state of the solder ball according to the embodiment after melting.

FIG. 4A is a perspective view showing an arrangement example of solder balls in a corner portion according to an embodiment.

FIG. 4B is a schematic view showing an example of a joint portion in the corner portion according to the embodiment.

FIG. 5 is a schematic view showing an example of a linear joint portion according to an embodiment.

FIG. 6 is a partial cross-sectional view showing a schematic view of an LED package manufactured using the solder ball according to the embodiment.

### DESCRIPTION OF EMBODIMENTS

Hereinafter, embodiments of the present invention will be described in detail with reference to the drawings. The same components are denoted by the same reference numerals, and the description thereof will be omitted as appropriate.

### 1. Embodiment

### (1) Configuration of Solder Ball

A solder ball 34 according to the present embodiment is an Au—Sn-based alloy which contains Sn of 19 mass % or more and 25 mass % or less, a balance containing Au as a main component, any one additional element of Mg, Al, Si, Ti, V, Cr, Mn, and Ce, and is a uniform eutectic alloy made of Au₅Sn₁ and AuSn. A concentration of the additional element with respect to the entire solder ball 34 is 0.01 ppm by weight or more and less than 0.1 ppm by weight.

An Au—Sn-based alloy solder ball in the related art has a problem that irregularities are generated on a surface thereof, and in some cases, appearance defects due to shrinkage cavities occur. This is considered to be caused by generation of a non-uniform Au-rich phase near the surface of the solder ball during cooling in a solder ball manufacturing process.

In the solder ball 34 according to the present embodiment, since trace amounts Mg, Al, Si, Ti, V, Cr, Mn, and Ce are dispersed in AuSn, there are many nucleation sites during solidification, generation of a non-uniform Au-rich phase during cooling is prevented, and a uniform lamellar structure is formed by a first phase (also referred to as a Au-rich phase) mainly composed of AusSn and a second phase mainly composed of AuSn. Therefore, occurrence of irregularities on a surface and shrinkage cavities is prevented, and sphericity is improved. The improved sphericity is preferably 0.7% or less. Accordingly, occurrence of mounting failures in a ball mounter or clogging in a solder jet device can be prevented.

If the concentration of the additional element in the entire solder ball 34 is less than 0.01 ppm by weight, an effect of improving the sphericity of the solder ball is small, and this is not preferable. In addition, if the concentration of the additional element in the entire solder ball 34 is increased to 0.1 ppm by weight or more, there is no effect of improving the sphericity due to an influence of oxides, and an upper limit is 0.1 ppm by weight.

A spherical diameter of the solder ball 34 is not limited as long as the spherical diameter is within a range in which effects of the present invention are exhibited, but the spherical diameter is preferably 10 μm or more and 500 μm or less. In this range, a solder ball with uniform spherical diameter accuracy can be manufactured. A range of the spherical diameter is more preferably 20 μm or more and 400 μm or less, and even more preferably 50 μm or more and 300 μm or less. In the related art, if the spherical diameter of the solder ball is 500 μm or less, particularly 300 μm or less, a mounting failure in a ball mounter or clogging in a solder jet device is likely to occur when sphericity of the solder ball is not high, and productivity is likely to decrease. In the solder ball 34 in the present embodiment, the sphericity is improved, and a mounting failure in a ball mounter or clogging in a solder jet device can be prevented from occurring.

When the concentration of the additional element is within the above range, an oxide film on the surface of the solder ball 34 is reliably melted during melting, resulting in good wettability. The wettability is presumably affected by the oxide film on the surface of the solder ball, and when the concentration of the additional element is outside the above range, it is considered that the oxide film is difficult to be melted, resulting in low wettability.

### (2) Method for Manufacturing Solder Ball

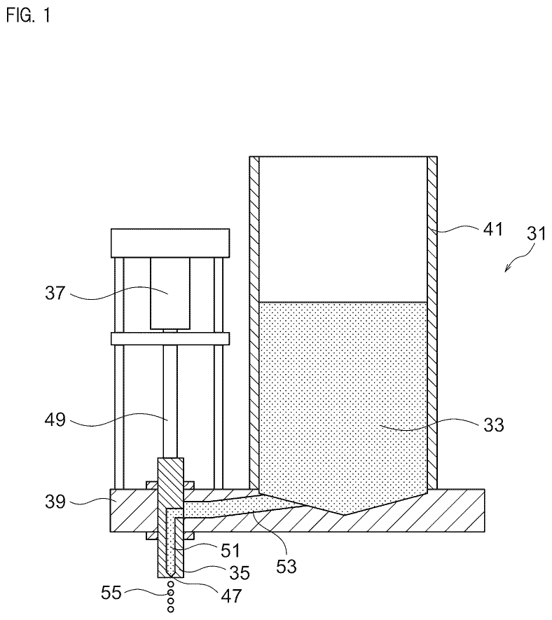

The solder ball 34 is preferably formed by a uniform droplet spray method (UDS method) in order to obtain uniform spherical diameter accuracy. An apparatus for manufacturing the solder ball 34 by the UDS method will be described with reference to FIG. 1. A USD manufacturing apparatus 31 shown in FIG. 1 includes a nozzle 35 that causes a molten solder 33 to flow downward, a vibration device 37 that vibrates the nozzle 35, a nozzle frame 39 that slidably holds the nozzle 35, and a solder storage tank 41. The nozzle 35 has an outlet 47 in a lower portion thereof. The nozzle 35 is connected to the vibration device 37 via a steel connecting rod 49. In the solder storage tank 41, the molten solder 33 is held at a temperature higher than a melting point by a predetermined temperature. The nozzle 35 has a nozzle path 51. A distal end of the nozzle path 51 is connected to the outlet 47 in the lower portion of the nozzle. The molten solder 33 stored in the solder storage tank 41 passes through a frame path 53 and the nozzle path 51 and flows out from the outlet 47. The USD manufacturing apparatus 31 causes the molten solder 33 to flow out from the outlet 47 while vibrating the nozzle 35 by the vibration device 37, thereby separating the flowed molten solder 33 into droplets 55. The method for manufacturing a solder ball can be performed in the same manner as the method described in PTL 3, except for the above. In the method for manufacturing a solder ball using the USD manufacturing apparatus 31, a droplet size becomes uniform, and the solder ball 34 having a highly accurate spherical diameter can be generated.

### (3) Method for Analyzing Concentration

A method for analyzing an element concentration will be described. The element concentration is separately analyzed by ICP-MS and ICP-OES depending on the concentration range. When the concentration range is less than 100 ppm by mass, the element concentration can be analyzed by inductively coupled plasma mass spectrometry (ICP-MS). When the concentration range is 100 ppm by mass or more, the element concentration can be analyzed by inductively coupled plasma optical emission spectrometry (ICP-OES).

### (Regarding ICP-MS)

### <Sample Pretreatment Method>

As an analyzer, one (device model number: Agilent 8800) manufactured by Agilent Technologies, Inc. is used. A procedure of a pretreatment is as follows. A solder ball (0.1 g) is weighed, 20 ml of aqua regia (composition: hydrochloric acid and nitric acid are mixed at a ratio of 3:1) is added to the solder ball, and the mixture is heated to approximately 200° C. to be melted. After the molten solder is allowed to cool, the mixture is transferred into a volumetric flask (volume: 100 mL) made of polypropylene (hereinafter, referred to as “made of PP”), and a volume is adjusted to a constant volume with ultrapure water. As a decomposition container, a quartz glass beaker is used to avoid contamination with impurities.

### <Analysis Method>

As an analysis method, a standard addition method is adopted. Specifically, 10 mL of the solution is placed in each of a plurality of PP volumetric flasks (volume: 100 mL), 2 mL of a solution obtained by diluting a single element standard solution of an element to be analyzed (Mg, Al, Si, Ti, V, Cr, Mn, Ce) to 100 μg/L is added stepwise to each PP volumetric flask, and then an extrapolated value when the addition amount is assumed to be 0 is taken as an analysis value of a target element based on an analysis value of each of the solutions whose volumes have been adjusted to a constant volume. As the single element standard solution, a reagent manufactured by Kanto Chemical Co., Inc. is used.

### <Measurement>

In the ICP-MS analysis method, interference is caused by generated polyatomic ions, and the background increases. Therefore, the measurement is performed by cool plasma (output: 600 W) to reduce an influence of interference ions.

### (Regarding ICP-OES)

### <Sample Pretreatment Method>

As an analyzer, one (device model number: iCAP 6500) manufactured by Thermo Fisher Scientific Inc. is used. A procedure of a pretreatment is as follows. A solder ball (1.0 g) is weighed, 20 mL of aqua regia (composition: hydrochloric acid and nitric acid are mixed at a ratio of 3:1) is added to the solder ball, and the mixture is heated to approximately 200° C. to be melted. After the molten solder is allowed to cool, the mixture is transferred into a volumetric flask (volume: 100 mL) made of borosilicate glass (hereinafter, referred to as “made of glass”), and a volume is adjusted to a constant volume with aqua regia which has been heated and degassed.

### <Analysis Method>

As an analysis method, a standard addition method is adopted. Specifically, 10 mL of a solution is placed in each of a plurality of glass volumetric flasks (volume: 100 mL), 0.1 mL of a single element standard solution (1000 μg/L) of an element to be analyzed (Sn) is added stepwise to each PP volumetric flask, and then an extrapolated value when the addition amount is assumed to be 0 is taken as the analysis value of the target element based on the analysis value of each of the solutions whose volumes have been adjusted to a constant volume. As the single element standard solution, a reagent manufactured by Kanto Chemical Co., Inc. is used.

### <Measurement>

A wavelength of Sn: 226.8 nm is measured by ICP-OES.

### (4) Method for Mounting and Joining Solder Ball

The solder ball 34 according to the present embodiment can be used as a joint material for a sealing package that hermetically seals an electronic device such as a semiconductor light emitting device formed by mounting a semiconductor light emitting element on a circuit board, an SAW filter, an FBAR filter, and a crystal resonator, or as a joint material for other semiconductor devices.

When the solder ball 34 according to the present embodiment is mounted on a joint surface as the joint material for the sealing package or other semiconductor devices described above, the solder ball 34 can be mounted using, for example, a ball mounter. For example, a ball mounter described in JP 2012-256748 A may be used. The ball mounter includes, for example, a ball arrangement plate with a suction hole at a mounting position of the solder ball 34, and after absorbing and holding the solder ball 34 on the ball arrangement plate, the ball arrangement plate is conveyed to the joint surface and placed on the joint surface coated with flux. The solder ball 34 is adhered to the joint surface by an adhesive force of the flux. By using the ball mounter, a plurality of solder balls can be mounted collectively.

When the solder ball 34 according to the present embodiment is mounted as the joint material for the sealing package or other semiconductor devices described above, the solder ball 34 can be mounted using, for example, a solder jet device (manufactured by PacTech). The solder jet device loads the solder ball 34 into a microtube such as a capillary, irradiates the solder ball 34 with a laser beam to melt the solder ball 34, and at the same time pushes the solder ball 34 out with an inert gas or the like, temporarily fixes the solder ball 34 to the joint surface, and then places and mounts the solder ball 34 on the joint surface. By using the solder jet device, the solder ball 34 can be temporarily fixed to the joint surface directly without using flux, and thus defects caused by flux, such as occurrence of voids and joint defects, can be inhibited. Mounting the solder ball 34 using the solder jet device may be applied in combination with a bump or the like formed on the joint surface.

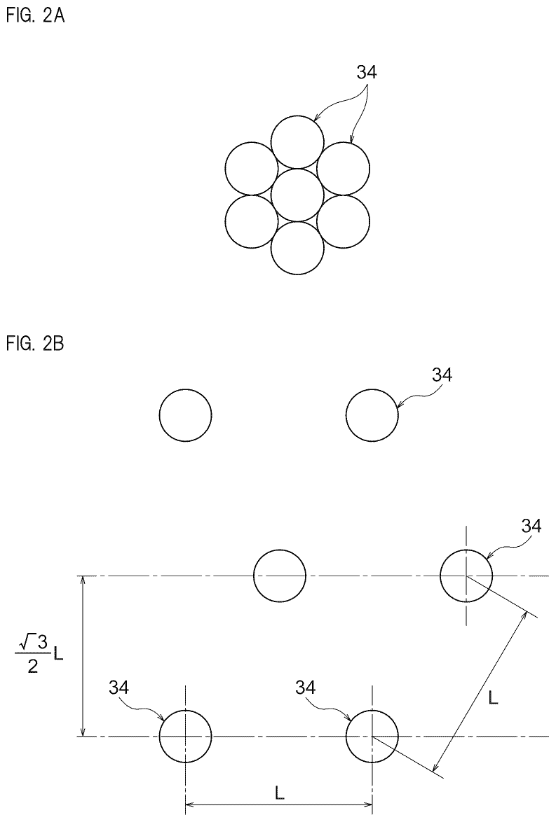

FIG. 2A is a plan view showing an example in which solder balls 34 according to an embodiment are disposed in a close-packed manner. As shown in FIG. 2A, the solder balls 34 may be disposed so as to be close-packed.

FIG. 2B is a plan view showing an example in which the solder balls 34 according to the embodiment are disposed at an interval L. As shown in FIG. 2B, the solder balls 34 may be disposed on the joint surface at the interval L represented by the following equation (1).

$$L = √ ( 2 {R}_{1}^{3} / 3 t ) \qquad ( 1 )$$

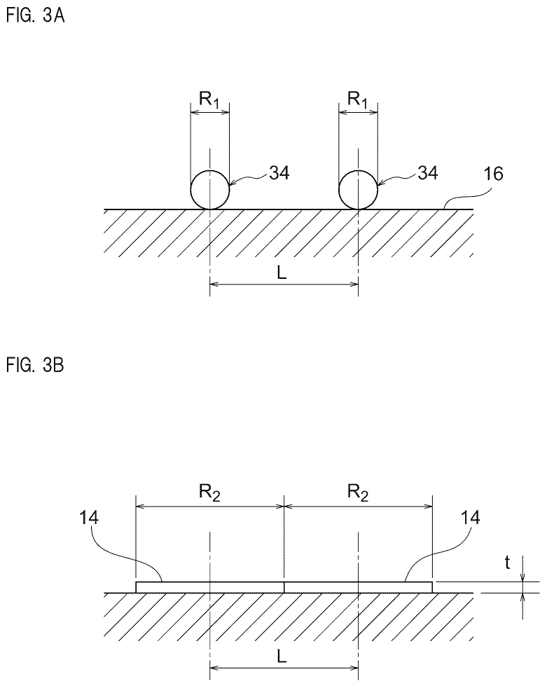

FIG. 3A is a schematic end view showing an example of a state of the solder balls 34 according to the embodiment before melting, and FIG. 3B shows a schematic end view showing an example of a state of the solder balls 34 according to the embodiment after melting. Here, a case in which the solder balls 34 are mounted on, for example, a joint surface of a substrate 16, the solder balls 34 spread by melting to form joint portions 14 will be described. The solder balls 34 having a spherical diameter R₁ are disposed at the interval L before melting. The solder ball 34 spreads by melting, and becomes the joint portion 14 having a diameter R₂ and a thickness t.

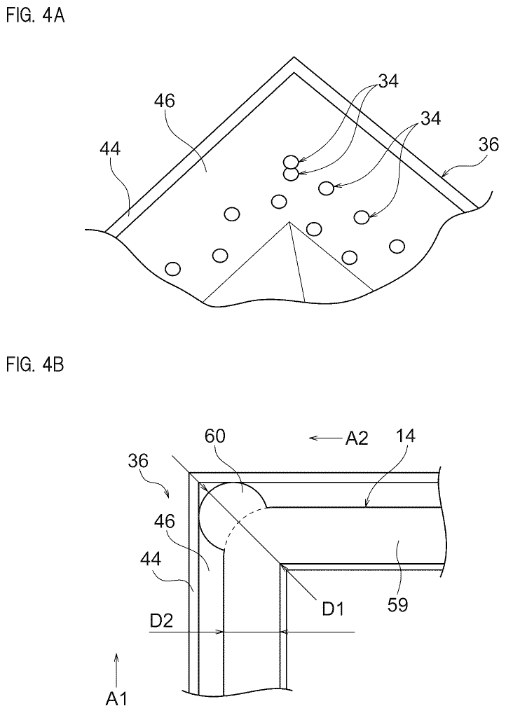

FIG. 4A is a perspective view showing an arrangement example of the solder balls 34 in a corner portion according to an embodiment. In this case, the solder balls 34 are mounted on a conductive layer 46 provided on a flange portion 44 of a substrate 36 having a corner portion by using a solder jet device, and the solder balls 34 are melted to form the joint portion 14, and a surface of the conductive layer 46 becomes a joint surface.

FIG. 4B is a schematic view showing an example of the joint portion 14 in the corner portion according to the embodiment. A mating surface to be joined (not shown) is aligned and faces the joint surface of the substrate 36 on which the solder balls 34 are mounted as shown in FIG. 4A, and the solder balls 34 are melted by heating in this state, and then are cooled and solidified, so that the joint portion 14 shown in FIG. 4B is formed. The joint portion 14 electrically connects the joint surface of the substrate 36 to the mating surface to be joined to the joint surface. The joint portion 14 shown in FIG. 4B has a base joint portion 59 and an extension portion 60.

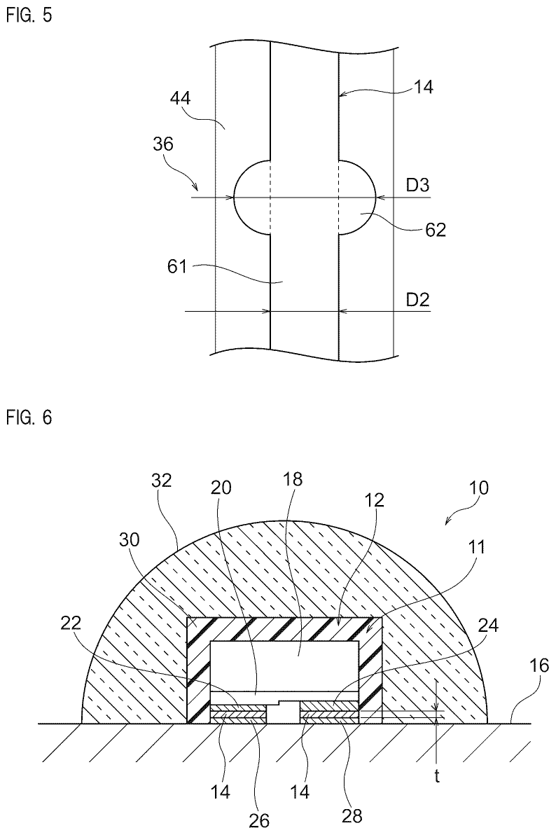

FIG. 5 is a schematic view showing an example of a linear joint portion according to an embodiment. The above extension portion may be formed at a regular interval in a region other than the corner portion, for example, in a linear portion as shown in FIG. 5.

After the ball bumps 34 are mounted on the joint surface as described above, the mating surface to be joined is aligned and faces the joint surface, and the solder balls are melted by heating in this state, and then cooled and solidified to form the joint portion, and the joint surface is electrically connected to the mating surface to be joined to the joint surface. The method for mounting and joining a solder ball can be performed in the same manner as the method described in PTL 3, except for the above.

### (5) Action and Effect

If an Au-rich phase is precipitated in an Au—Sn-based alloy solder ball, even if there are no shrinkage cavities, a polyhedral shape like a mirror ball is obtained, and the sphericity becomes low, and thus, a mounting failure in a ball mounter or clogging in a solder jet device occurs.

In the solder ball 34 according to the present embodiment, since any one of Mg, Al, Si, Ti, V, Cr, Mn, and Ce is dispersed at 0.01 ppm by weight or more and less than 0.1 ppm by weight in AuSn, there are many nucleation sites during solidification, generation of a non-uniform Au-rich phase during cooling is prevented, and a uniform lamellar structure is formed by a first phase (also referred to as a Au-rich phase) mainly composed of AusSn and a second phase mainly composed of AuSn. Therefore, the solder ball 34 according to the present embodiment is a solder ball with a smooth mirror surface in which the occurrence of irregularities on the surface and shrinkage cavities is prevented and the sphericity is improved. Accordingly, occurrence of a mounting failure in a ball mounter or clogging in a solder jet device can be prevented.

Any metal element that is more easily oxidized than Sn may be used as an additional element to the Au—Sn-based alloy. The same effect can be obtained by adding any one of Mg, Al, Si, Ti, V, Cr, Mn, and Ce at 0.01 ppm by weight or more and less than 0.1 ppm by weight.

### (6) Semiconductor Light Emitting Device Manufactured Using Solder Ball According to Present Embodiment

A light emitting diode (LED) package 10 shown in FIG. 6 includes a semiconductor light emitting device 11 as a joint structure. The semiconductor light emitting device 11 includes an LED chip 12 as a first structure and the substrate 16 as a second structure joined to the LED chip 12 via the joint portion 14 formed of a solder alloy. The LED chip 12 is a light emitting element including a substrate 20 and a crystal layer 18 that is formed on the substrate 20 and includes a light emitting layer. An electrode 22 and an electrode 24 are formed on a surface of the substrate 20 opposite to a side where the crystal layer 18 is formed. The electrode 22 and the electrode 24 are made of a conductive material such as Au, Ag, Cu, or Al. The LED chip 12 is a flip-chip type light emitting element including the electrodes 22 and 24 facing downward. One of the electrodes 22 and 24 is an n-side electrode, and the other is a p-side electrode. The joint portion 14 is formed of an Au—Sn-based alloy containing Sn of 19 mass % or more and 25 mass % or less and containing Au as a main component, and contains any one additional element of Mg, Al, Si, Ti, V, Cr, Mn, and Ce at a concentration of 0.01 ppm by weight or more and less than 0.1 ppm by weight. Except for the above, a configuration same as that of the semiconductor light emitting device described in PTL 3 can be obtained.

The LED package 10 can be applied to a light source such as an automobile headlight requiring high luminance.

In addition to a joint material for the LED package 10, the solder ball 34 according to the present embodiment can be used as a joint material for a sealing package that hermetically seals an electronic device such as a semiconductor light emitting device formed by mounting a semiconductor light emitting element on a circuit board, an SAW filter, an FBAR filter, and a crystal resonator, or as a joint material for other semiconductor devices.

### 2. Examples

Hereinafter, the present invention will be described in detail based on Examples, but this is merely an example of the present invention, and the present invention is not limited to Examples in any way.

### (Sample)

Solder balls shown in Table 1 were prepared by the procedure described in “(2) Method for manufacturing solder ball” described above. First, Au, Sn, and additional elements were weighed, and an ingot was prepared by high-frequency melting. The additional elements were consumed as oxides during granulation, and thus, 5 times to 10 times an amount of a desired component concentration was added. The ingot was placed in a solder storage tank, the solder storage tank was heated to 385° C. in an atmosphere of N₂−5 vol % H₂, and a frequency of a piezo element was adjusted to 10 kHz to 50 kHz to obtain solder balls with the desired spherical diameter. Then, 10000 or more solder balls were prepared.

### (Evaluation Method)

A concentration of Sn in each of the prepared solder balls was evaluated by an ICP-OES method, and a concentration of each of the additional elements was evaluated by an ICP-MS method using 1 g of each of the solder balls. A spherical diameter and sphericity (%) were measured based on a coordinate data of an outline of a two-dimensional image taken from directly above the solder ball by using an image processing device. The spherical diameter was set as a diameter (D1) of a reference circle obtained by a least squares method. The sphericity (%) was calculated by determining a diameter (D2) of a circumscribed circle and a diameter (D3) of an inscribed circle to calculate (D2−D3)/D1×100, and was taken as a simple average of 50 solder balls. Results are shown in Table 1.

TABLE 1

| | | | | | | | | | | | | Spherical | |
|---|---|---|---|---|---|---|---|---|---|---|---|---|---|
| | | Concentration in obtained solder ball (Sn is wt %, and others are ppm by weight) | | | | | | | | | | diameter | Sphericity |
| | No | Au | Sn | Mg | Al | Si | Ti | V | Cr | Mn | Ce | (μm) | (%) |
| Comparative | 1 | Balance | 18 | 0.05 | | | | | | | | 200 | 0.75 |
| Example | | | | | | | | | | | | | |
| Example | 2 | Balance | 19 | 0.05 | | | | | | | | 200 | 0.58 |
| Example | 3 | Balance | 23 | 0.05 | | | | | | | | 200 | 0.6 |
| Example | 4 | Balance | 25 | 0.05 | | | | | | | | 200 | 0.65 |
| Comparative | 5 | Balance | 26 | 0.05 | | | | | | | | 200 | 0.8 |
| Example | | | | | | | | | | | | | |
| Example | 6 | Balance | 20 | | 0.05 | | | | | | | 125 | 0.58 |
| Example | 7 | Balance | 20 | | | 0.05 | | | | | | 125 | 0.52 |
| Example | 8 | Balance | 20 | | | | 0.05 | | | | | 125 | 0.55 |
| Example | 9 | Balance | 20 | | | | | 0.05 | | | | 125 | 0.56 |
| Example | 10 | Balance | 20 | | | | | | 0.05 | | | 125 | 0.49 |
| Example | 11 | Balance | 20 | | | | | | | 0.05 | | 125 | 0.52 |
| Example | 12 | Balance | 20 | | | | | | | | 0.05 | 125 | 0.5 |
| Comparative | 13 | Balance | 22 | | | 0 | | | | | | 50 | 0.86 |
| Example | | | | | | | | | | | | | |
| Example | 14 | Balance | 22 | | | 0.01 | | | | | | 50 | 0.64 |
| Example | 15 | Balance | 22 | | | 0.09 | | | | | | 50 | 0.63 |
| Comparative | 16 | Balance | 22 | | | 0.10 | | | | | | 50 | 0.75 |
| Example | | | | | | | | | | | | | |
| Example | 17 | Balance | 25 | | | | | 0.08 | | | | 10 | 0.62 |
| Example | 18 | Balance | 25 | | | | | 0.08 | | | | 50 | 0.58 |
| Example | 19 | Balance | 25 | | | | | 0.08 | | | | 300 | 0.59 |
| Example | 20 | Balance | 25 | | | | | 0.08 | | | | 500 | 0.65 |
| Example | 21 | Balance | 19 | | | | | | 0.01 | | | 100 | 0.58 |
| Example | 22 | Balance | 19 | | | | | | 0.02 | | | 100 | 0.52 |
| Example | 23 | Balance | 19 | | | | | | 0.03 | | | 100 | 0.52 |
| Example | 24 | Balance | 19 | | | | | | 0.08 | | | 100 | 0.57 |
| Example | 25 | Balance | 19 | | | | | | 0.09 | | | 100 | 0.64 |
| Example | 26 | Balance | 20 | | 0.04 | | | | | | | 150 | 0.55 |
| Example | 27 | Balance | 19 | | | | 0.06 | | | | | 150 | 0.52 |
| Example | 28 | Balance | 21 | | | | | | | 0.07 | | 150 | 0.55 |

### (Evaluation Result)

In Comparative Examples No. 1 and No. 5 and Examples No. 2 to No. 4, the concentration of Sn was 18 wt % to 26 wt %, and a concentration of Mg in each of the solder balls was 0.05 ppm by weight. The concentration of Sn was 19 wt % to 25 wt %, and the sphericity was 0.58% to 0.65%, which was high sphericity.

In Examples No. 6 to No. 12, Al, Si, Ti, V, Cr, Mn, and Ce were investigated as additional elements in the solder balls. A concentration of additional elements in each of the solder balls measured by ICP-MS was 0.05 ppm by weight, and a spherical diameter was 125 μm. The sphericity was 0.49% to 0.58%, which was high sphericity.

Comparative Examples No. 13 and No. 16 and Examples No. 14 and No. 15 were evaluated with a concentration of Si in each of the solder balls of 0 ppm by weight to 0.1 ppm by weight and a spherical diameter of 50 μm. When the concentration of Si, which was an additional element, was 0.01 ppm by weight or more and less than 0.1 ppm by weight, sphericity was 0.63% and 0.64%, respectively, which was high sphericity.

In Examples No. 17 to No. 20, the concentration of Sn in each of the solder balls was 25 wt %, a concentration of V was 0.08 ppm by weight, and a spherical diameter was 10 μm to 500 μm. Sphericity was 0.58% to 0.65%, which was high sphericity.

In Examples No. 21 to No. 25, the concentration of Sn in each of the solder balls was 19 wt %, a concentration of Cr was 0.01 ppm by weight to 0.09 ppm by weight, and a spherical diameter was 100 μm. Sphericity was 0.52% to 0.64%, which was high sphericity.

In Example No. 26, the concentration of Sn in the solder ball was 20 wt %, and a concentration of Al was 0.04 ppm by weight, in Example No. 27, the concentration of Sn in the solder ball was 19 wt %, and a concentration of Ti was 0.06 ppm by weight, and in Example No. 28, the concentration of Sn in the solder ball was 21 wt %, and a concentration of Mn was 0.07 ppm by weight, and a spherical diameter in each of these Examples was 150 μm. Sphericity was 0.52% to 0.55%, which was high sphericity.

### REFERENCE SIGN LIST

10 LED package
11 semiconductor light emitting device
12 LED chip
14 joint portion
16 substrate
22, 24 electrode
26, 28 electrode
34 solder ball
36 substrate
44 flange portion
46 conductive layer
59 base joint portion
60 extension portion
61 base joint portion
62 extension portion

1. A solder ball comprising:
Sn of 19 mass % or more and 25 mass % or less;
a balance containing Au as a main component; and
any one additional element of Mg, Al, Si, Ti, V, Cr, Mn, and Ce, wherein
a concentration of the additional element with respect to the entire solder ball is 0.01 ppm by weight or more and less than 0.1 ppm by weight.

2. The solder ball according to claim 1, wherein
the solder ball has a spherical diameter of 500 μm or less.

3. The solder ball according to claim 1, wherein sphericity is 0.7% or less.

4. The solder ball according to claim 2, wherein
sphericity is 0.7% or less.
